(19) United States
(12) Patent Application Publication
(10) Pub. No.: US 2024/0274735 A1
(43) Pub. Date: Aug. 15, 2024

(54) SOLAR PANEL FOR A ROADWAY, SOLAR ROADWAY AND METHOD OF CONSTRUCTING THE SOLAR PANELS

(71) Applicant: DM SOLAR LIMITED, Worthing (GB)

(72) Inventor: Dominic MANGLES, Worthing (GB)

(73) Assignee: DM SOLAR LIMITED, Worthing (GB)

(21) Appl. No.: 18/560,303

(22) PCT Filed: May 11, 2022
(86) PCT No.: PCT/IB2022/054396

§ 371 Date: Nov. 10, 2023

(30) Foreign Application Priority Data
May 11, 2021 (GB) 2106699.8

(51) Int. Cl. H01L 31/048; H01L 31/0296; H02S 20/20

(52) U.S. Cl. CPC H01L 31/0488; H02S 20/20; H01L 31/0296

(57) ABSTRACT

The invention relates to a solar panel (12) for a roadway (10), a solar roadway comprising an array of solar panels, and a method of constructing the solar panels. The invention relates specifically to the use of the roadway for the generation of electricity. A solar panel (12) for a roadway comprises a base layer (44), a layer (40,42) including a PV material, and a top layer (30), the top layer comprising tempered glass granules with an average size of approx. 2-3 mm embedded in a crystal resin, the top layer having multiple substantially parallel grooves formed therein, the grooves being approx. 3 mm deep. The grooves allow air to escape from underneath the tyres of a vehicle and reduce the road noise generated by the tyres.

### FIELD OF THE INVENTION

The invention relates to a solar panel for a roadway, a solar roadway comprising an array of solar panels, and a method of constructing the solar panels. The invention relates specifically to the use of the roadway for the generation of electricity.

The term “roadway” should be interpreted broadly in accordance with the widespread utility of the invention, and encompasses in particular all areas designed for vehicular traffic, including public and private parking areas and driveways. The term also includes airport runways, airport taxiways, cycle paths, footpaths and the like.

Directional and orientational terms such as “top”, “bottom” etc. refer to a generally horizontal roadway unless indicated otherwise.

### BACKGROUND TO THE INVENTION

The creation of low-carbon or preferably zero-carbon energy is a widespread goal in order to combat global warming. Creating energy from renewable sources is often preferred over other zero-carbon sources such as nuclear. Solar energy is a widely preferred renewable source, and comprises the conversion of electromagnetic (light) energy into electricity, typically by way of solar panels comprising a photovoltaic (PV) material.

A disadvantage of solar energy is that it is relatively diffuse. It is therefore necessary to provide large arrays of solar panels, covering significant areas, in order to provide the quantities of electricity required to meet the needs of a town or city. Covering large areas of land with solar panels is not always the best use of that land.

A benefit of solar energy is that it can be used in a distributed energy network, i.e. the electricity which is generated can be used locally and it is not necessary to link the solar panels to the national electrical network (national grid).

The road network covers a large area of many countries and it has been appreciated that the area occupied by roadways might also be utilised for the creation of electricity from solar energy. Roadways are a vital commercial infrastructure and provide the arterial network to the modern way of life. By 1902 Hooley had patented the process of heating tar, adding slag to the mix and then breaking stones within the mixture to form a relatively smooth road surface. Having perfected the operation, Hooley began transforming road surfaces and Radcliffe Road in Nottingham, UK became the first tarmac road in the World. Since then the road formula has stayed much the same, but the land area which has been covered by roadways has increased significantly.

The storage of large amounts of electrical energy has traditionally not been undertaken, with the result that the electricity network connecting the power stations and other sources of electricity to the commercial and domestic premises where the electricity is used, is continuously seeking to balance the supply and demand. The widespread switch to electric vehicles which is expected to occur over the coming years is likely to result in an increase in the demand for electricity. Also, it is expected that the distances which people travel by vehicle will continue at current levels or will increase. Studies have suggested that the increased use of electric vehicles, and the distances which people are expected to travel in those vehicles, are together likely to increase demand significantly. This increased demand will place a huge burden on the sources of electricity and also upon the electricity network (much of the infrastructure of which, in the UK for example, is largely unchanged since the 1960's).

The practicalities of charging millions of electric vehicles by way of dedicated charging stations located above-ground is expected to be a limiting factor as the number of electric vehicles increases. The issue is not just in the above-ground infrastructure which will be required to provide the increased number of charging stations, but also the below-ground work required to interconnect those charging stations and which is likely to involve long term works and significant upheaval to residents and businesses alike.

National electricity networks are expected to remain as the backbone infrastructure in the future, with subsidiary networks (or micro-grids) providing support in high demand areas and providing localised energy storage management for residents and businesses. Including sources of electrical energy in a micro-grid can allow new residential (and other) developments to be totally self-sufficient in electricity so that they do not draw from the national network even at peak times.

Balancing the supply and demand for electricity will likely become more difficult as the proportion of electricity which is generated by renewable sources increases, primarily because those sources are not always available. Another critical factor in an electricity network (both nationally and locally) will therefore be the storage of electrical energy.

In particular, it is expected that it will become necessary to be able to store large quantities of electrical energy during periods when the supply exceeds the demand so that there is sufficient energy available during other periods when the demand exceeds the supply. The presently-preferred method to store electrical energy is by way of batteries, although super-capacitors can also be used for smaller amounts of energy storage.

### DESCRIPTION OF THE PRIOR ART

US patent application 2005/0199282 describes solar panels embedded in a roadway. The solar panels comprise PV material and are modular. The roadway comprises an alternating array of solar panels and non-solar panels, the non-solar panels providing structural support so that the solar panels do not bear the full weight of traffic upon the roadway. Each solar panel is sandwiched between a transparent top layer and a base layer which includes electrical wires to connect to other panels and also to exterior components. The top layer is abrasion resistant, for example acrylic, polycarbonate, tempered glass or annealed glass. The exterior components can be capacitors to store the electricity which is generated and inverters to allow the electricity to be transmitted and used elsewhere. The top layer can include projections or depressions to provide the required grip for vehicles travelling on the roadway. It is noted that the PV material will generate heat and that heat can be used to melt snow and ice which is present on the roadway. In addition, dedicated electrical conductors can be embedded into the panels to generate heat in order to melt snow and ice, the electricity being provided to those conductors by the PV material of the panel or from external sources.

US2019/0123216 discloses a structure including PV material for a roadway which structure is laid on top of an existing road. The top surface can include friction elements in lines, circles or other geometric shapes, and which can be grooves cut into the surface. The top surface has a desired macrostructure to disperse water and a desired microstructure to provide grip. The top surface has a transparency of 50% 95% at the relevant wavelengths of 500 nm-700 nm. The road surface can comprise glass grains which are 0.1 mm to 10 mm in size.

WO2019/081863 discloses a roadway comprising panels (or tiles) with PV material, and provides a common positive and a common negative electrical rail alongside the roadway (or across a wide roadway). The individual panels have electrical contacts to provide a connection to the common rails in a chosen parallel/series arrangement.

US2018/0102730 discloses a modular solar roadway comprising multiple panels including PV material which can be fitted and replaced individually. The roadway incorporates controllers and sensors to detect the presence of pedestrians and/or vehicles upon the roadway. Heating elements are provided to prevent the build-up of ice and snow on the roadway surface. The roadway also includes coils for inductive charging of a vehicle on the roadway. The controllers can transmit and receive data to/from a vehicle. The panels can include LEDs allowing the display of roadway lines and other information to passing vehicles. Each controller can communicate with other controllers along the roadway. The electricity generated by the panels can be stored in capacitors or batteries or passed to an external network by way of inverters. The top surface of the panels is glass, which can be textured or patterned as desired. Protrusions of the top surface can refract and diffuse the incident light and enhance the generation of electricity. The glass can be coated to increase its wear resistance, and tempered or treated by ion-exchange to increase its resistance to damage. The top surface can be laminated to increase its stiffness and strength. The PV material can be printed onto a laminate layer and can comprise monocrystalline cells or thin-film solar cells.

WO2015/160512 provides a general description of a roadway which incorporates inductive charging of a moving vehicle. Multiple charging pads are provided in tiles or panels along the roadway. The charging pads in each panel can be separate or overlapping. Each charging pad can be connected to a common electrical rail laid alongside the roadway by switches which are actuated by a local controller. The local controllers are in communication with a central distribution controller. The controllers communicate with a vehicle and receive a signal from the vehicle to commence charging. The controllers are able to determine the position of the vehicle and the path of travel of the vehicle and can obtain the vehicle's speed from the vehicle or from sensors in the roadway. The charging pads can be actuated sequentially according to the vehicle's speed, or each charging pad can detect and react to the vehicle's presence, or the charging pads can communicate the imminent arrival of the vehicle to its neighbours.

### SUMMARY OF THE INVENTION

It is an object of the present invention to provide solar panels for a roadway and a roadway incorporating a number of solar panels, whereby the roadway can be a source of electricity. The electricity which is generated can be used locally, for example to display information to vehicles on the roadway and/or to melt snow and ice on the roadway. Alternatively or additionally the electricity which is generated can be stored and/or can be transmitted to a local or national electricity network. In common with the prior art the panels can be removed individually and replaced as required.

It is another object of the present invention to provide a solar panel of which a large proportion is constructed from materials which would otherwise be waste. Certain of the materials utilised in the invention can be plastics from various sources, and in particular plastics which cannot be recycled for their original or related purpose and which would otherwise be scrapped. Another material can be rubber which is preferably from used vehicle tyres. Waste non-recyclable plastics and used vehicle tyres are both widely available and the large scale use of these materials can contribute to a significant reduction in waste material going to landfill.

According to the first aspect of the invention there is provided a solar panel for a roadway, the panel comprising a base layer, a layer including a PV material, and a top layer, the top layer comprising tempered glass granules with an average size of approximately 2-3 mm embedded in a crystal resin, the top layer having multiple substantially parallel grooves formed therein, the grooves being approx. 3 mm deep and approx. 5 mm apart.

In the assembled roadway it is arranged that the panel is laid so that the grooves are substantially perpendicular to the direction of travel, i.e. they are aligned across rather than along the roadway. The grooves in the top layer not only provide grip to the tyres of vehicles upon the roadway but are sized to reduce road noise. In this respect it is recognised that much of the road noise generated by vehicles is caused by air being compressed between the tyre and the roadway, noise being generated as the compressed air escapes from underneath the tyre at high pressure and at high velocity. Road noise is a significant concern for a roadway with a surface of glass or the like as the roadway is typically significantly smoother (at a small scale) than a roadway of asphalt, the roadway of asphalt having many more surface imperfections allowing the air to escape from underneath the tyre. Providing grooves which allow the air to escape from underneath the tyre can significantly reduce the noise which is generated on a roadway with a surface of glass granules and resin.

Preferably the resin has a similar transparency and optical clarity to that of the tempered glass granules, and ideally a substantially identical transparency and optical clarity. In such embodiments the resin and glass granules are substantially visually indistinguishable.

Preferably the crystal resin sets or hardens in ultraviolet light. Such resins are readily available and do not tarnish during long exposure to sunlight.

Desirably there is a first sheet of glass between the top layer and the PV layer. The first sheet of glass preferably comprises tempered low iron glass.

A first sheet of glass provides benefits during manufacture, in that the PV material can be applied to a substantially flat surface of glass rather than to the resin of the top layer. The first sheet of glass can be bonded to the top layer by crystal resin so as to form an integrated structure.

Preferably there is a second sheet of glass between the first sheet of glass and the PV layer. The second sheet of glass preferably also comprises tempered low iron glass. Preferably the first and second sheets of glass are both approx. 10 mm thick.

Providing two sheets of glass underneath the top layer facilitates the provision of additional electrical componentry without adversely affecting the PV layer, since that additional electrical componentry can be located between the first and second sheets of glass.

The additional electrical componentry may comprise LEDs and associated circuitry, the LEDs being configured to provide visual information to the road user. The visual information might provide “permanent” information such as replicating lane markings in the form of solid or dashed lines. The visual information might also provide traffic information and/or signage. The visual information might additionally or alternatively provide temporary information such as warnings of accidents or lane closures ahead of the vehicle. It will be appreciated that even the “permanent” visual information can be modified by switching on and off selected LEDs so that lane markings for example can be changed temporarily in the event of an accident or roadworks. Alternatively or additionally, in roadways in which the presence of vehicles is detected it can be arranged that the lane marking and other signage is illuminated only when vehicles are present at the relevant location.

Further additional electrical componentry may be located between the top layer and the first sheet of glass. For example, the panel preferably includes one or more heating elements in the form of electrical conductors. Desirably the heating elements are of graphene. Desirably also the heating elements comprise threads or filaments of graphene oxide which are applied by atomic deposition to the first sheet of glass. Preferably the heating elements cover approx. 1% of the total area of the panel (in plan view). It will be understood that an electrical current passing through the heating elements between the top layer and the first sheet of glass will cause the top layer to heat up. This can melt any snow or ice which is lying upon the roadway. Locating the heating elements immediately underneath the top layer is advantageous as the heating elements are very close to the road surface where their heating effect is maximised. It will also be understood that the heating elements are opaque so that their area should be minimised whilst still providing the heating effect required. Furthermore, since graphene is solar reactive it can act as a secondary energy collector in terms of thermal energy and also solar energy.

The heating elements may be connected to further electrical conductors at one or more of the edges of the panel. For example, the heating elements may be aligned parallel to each other and cross the panel; further electrical conductors may be aligned perpendicular to the heating elements. In this way the further electrical conductors can be connected to multiple heating elements, ideally the opposing ends of each heating element, and can provide electricity to all of the heating elements in parallel. The further electrical conductors are preferably provided by respective ribbons of copper, ideally located along opposing edges of the panel. In embodiments in which the heating elements are connected by wiring to other components of the panel, two separate heating regimes can be used. The first heating regime can be a low-power regime suitable for providing frost protection for example. Heat generated by other components of the panel is transmitted by the wiring to the heating element(s) so that in this first heating regime the wiring transmits heat rather than electricity. In the second, high-power, heating regime electrical energy is also transmitted to the heating elements by the wiring.

Instead of further electrical conductors, the heating elements preferably operate inductively, i.e. the heating elements can comprise a loop or ring of conductive material and an electrical current can be induced to flow around the loop when heating is required.

The further additional electrical componentry preferably includes one or more temperature sensors. The temperature sensors can operate with the heating elements so that the heating elements are switched on when a predetermined low temperature is detected, or can be switched off when a predetermined high temperature is detected, or both. If there are two heating regimes as indicated above, the temperature sensors can also determine an intermediate temperature when the first heating regime is switched on.

Desirably, the first and second sheets of glass are bonded together by crystal resin. The additional electrical componentry between the first and second sheets of glass are preferably embedded in the crystal resin. The crystal resin effectively creates an integrated layer of glass and additional electrical componentry between the top layer and the PV layer.

The solar panel can include one or more inductive charging coils for the purpose of transmitting electromagnetic energy to a vehicle using the roadway, whereby to charge the battery of the vehicle as it travels along the roadway. Whilst it is preferable for the heating elements to be located relatively close to the top surface of the panel, it is not necessary for the inductive charging coils to be so close to the top surface. In order to minimise the disruption of light transmitted to the PV material it is preferable for the charging coils to be underneath the PV layer, and ideally in the base layer.

Also, in embodiments having inductively-charged heating elements and inductive coils for charging a vehicle battery, it is necessary to ensure that the components can operate separately and do not interfere with each other. Preferably therefore, the heating elements do not overlie the vehicle charging coils. Accordingly, it is preferably arranged that a chosen portion of the panel includes the vehicle charging coils and does not include heating elements (and vice versa). Desirably the chosen portion comprises a strip spanning the panel, ideally spanning the central region of the panel.

Preferably the layer of PV material is mounted to the second sheet of glass (or alternatively to the first sheet of glass in those less preferred embodiments in which there is no second sheet of glass). Desirably the PV material comprises CdTe (cadmium telluride) and a backing layer of zinc magnesium oxide and copper thiocyanate. Such a PV material is known to have good electrical performance in substandard light conditions and is mechanically robust under load. Other PV materials could be used, for example CiGs (copper indium gallium selenide). In known fashion, the layer of PV material also includes the necessary electrical contacts connected to the PV material. A protective film is preferably applied over the PV material to lie between the PV material and the base layer in the solar panel.

Preferably the solar panel has a local controller, suitably including a microprocessor mounted to a printed circuit board. Desirably the local controller is located in the base layer. Preferably, all of the electrical componentry of the panel is connected to and controlled by the local controller. For example, the local controller can be connected to all of the sensors of the solar panel; it can include the management hardware and software for the PV material and for any inductive charging coils located in the panel. In particular, in embodiments having heating elements and temperature sensors, wiring for the temperature sensors is preferably bussed down holes through the panel by ribbon connector(s) to the local controller. Wiring is not required for the heating elements if they operate inductively as is preferred.

Preferably the solar panel has electrical contacts located at at least one of its edges and which can interconnect the local controller of one solar panel to the local controller of one or more neighbouring panel(s). The electrical contacts can also interconnect the local controller with an external controller. Preferably the external controller is a group controller connected to the local controllers of multiple solar panels.

In embodiments having vehicle charging coils, the solar panel can include one or more load sensors or strain gauges which can detect the presence of a vehicle upon the solar panel. The solar panel can also include communication means by which it can send and receive signals to and from a vehicle to indicate that the vehicle should be inductively charged. It can be arranged that each solar panel controls its own vehicle charging coils and reacts directly to the vehicle. It is preferable, however, for the vehicle charging to be coordinated by an external group controller with multiple panels communicating the location of the vehicle to the external controller and the external controller instructing the activation of the inductive charging coils sequentially as the vehicle passes along the roadway. Such a coordinated system can cater for latency of the sensors and also for delays in generating the inductive charge.

According to the second aspect of the invention there is provided a modular panel for a solar roadway, the panel comprising a base layer, a layer of PV material, a top layer, a first sheet of glass and a second sheet of glass between the top layer and the layer of PV material, and additional electrical componentry between the first and second sheets of glass.

The additional electrical componentry can be LEDs for example as explained above. As also explained above, providing two sheets of glass with additional electrical componentry therebetween separates the additional electrical componentry from the PV material and makes manufacture of the panel easier.

Preferably the first sheet of glass is located above the second sheet of glass. Desirably the first sheet of glass is less than approx. 15 mm thick, and preferably approx. 10 mm thick, and ideally exactly 10 mm thick. Desirably also the second sheet of glass is less than approx. 15 mm thick, and preferably approx. 10 mm thick, and ideally exactly 10 mm thick. Tests upon a modular panel sharing all aspects of the invention have shown that using glass sheets which are more than 10 mm thick provides a negligible benefit in loading performance but a non-negligible reduction in solar performance.

Preferably the first sheet of glass and the second sheet of glass are bonded together by a layer of crystal resin. Preferably also the additional electrical componentry is embedded in the layer of crystal resin. Desirably the layer of crystal resin is approx. 5 mm thick.

According to the third aspect of the invention there is provided a modular panel for a solar roadway, the panel comprising a base layer, a layer of PV material and a top layer, the top layer comprising tempered glass granules embedded in a crystal resin, the base layer including a rubber material.

References herein to rubber should be interpreted as vulcanised rubber.

Rubber is an extremely strong and durable material which is suited to long-term use in a panel providing a roadway. A base layer of rubber can be made to withstand loads of several tonnes repeatedly over an expected twenty-year lifetime.

Preferably the rubber material comprises granular and fibrous rubber and a polyurethane binder. Ideally the granular and fibrous rubber is made from recycled vehicle tyres. A suitable rubber material is manufactured by Rosehill Polymers Limited of Sowerby Bridge, West Yorkshire, as used for example in their patent application UK 2 564 090.

Notwithstanding that rubber is deformable and resilient, the base layer is preferably formed by compressing a mixture of granularised rubber and polyurethane binder under loads of around 100 tonnes. Ideally, the base layer is built up in stages, a chosen thickness of rubber and polyurethane binder being compressed and hardening in each stage. Such a base layer will have some deformability and resilience but will in practice be substantially incompressible during use. The glass layers which are mounted on top of the base layer in the solar panel, and the PV material, therefore do not need to accommodate significant deformation in use.

In addition, the base layer will act to spread the relatively localised load of a vehicle tyre across a larger area of the underlying ground.

Preferably the mixture of rubber granules and binder comprises approx. 92% rubber and approx. 8% polyurethane resin.

Preferably, the base layer is between approx. 100 mm and approx. 150 mm thick. Desirably between approx. 110 and approx. 125 mm thick, and ideally approx. 115 mm thick. The base layer preferably comprises the major portion of the overall thickness (depth) of the solar panel.

Desirably the base layer includes elements made of plastic material, ideally non-recyclable plastics which would otherwise go to waste. Preferably the base layer includes a plastic mounting for the local controller and its associated electrical cabling and connectors. In the event that the base layer includes a heat sink it can also include a plastic mounting for the heat sink.

Preferably, the base layer has at least one recess to accommodate the local controller and associated cabling and componentry. Desirably the recess is moulded into a part of the base layer during its construction. Preferably the recess accommodates the plastic mounting which in turn accommodates the local controller and associated cabling and componentry. Desirably, the plastic mounting is filled with resin, with the local controller, cabling and associated componentry embedded in the resin, to form an integrated base for the solar panel.

Holes can be formed (preferably drilled) in the base layer for cables to connect the local controller with other electrical components of the solar panel.

A resin material can if desired be used to seal any joints in the base layer. A resin can also be used to bond the base layer to the layer of PV material.

The panel is preferably rectangular, a rectangular shape being suitable for laying as tiles along a roadway. Preferably the panel has a length of between 2.0 metres and 5.0 metres, desirably between 3.0 metres and 4.0 metres, and ideally 3.5 metres. Preferably also the panel has a width of between 1.0 metre and 3.0 metres, desirably between 1.5 metres and 2.5 metres, and ideally 2.0 metres. It will be appreciated that a number of solar panels which are all 3.5 metres by 2 metres can be laid as adjacent tiles across and along a roadway. The electrical contacts of each panel can be connected to its neighbours, and also to common electrical busses running along the side edge of the roadway. Electrical storage units in the form of batteries or supercapacitors can be located at periodic intervals along the side of the roadway (to supplement any storage provided upon each of the panels). The electrical storage units can be connected to a local electricity network (micro-grid) and/or to the national network.

The features of each aspect of the invention may be combined with features of another aspect of the invention with which they are compatible. Also, preferred or optional features which are described in relation to one aspect of the invention can be utilised with other aspects of the invention with which they are compatible (not all of such optional features are identified for each aspect to avoid unnecessary duplication).

There is also provided a method of manufacturing the top layer of a solar panel for use in a roadway, the method comprising the steps of:
{i} locating four edging pieces upon a flat metallic work surface in the shape of a rectangle with chosen dimensions;
{ii} applying continuous and substantially parallel lines of wax to the work surface, the lines of wax being approx. 3 mm high and approx. 5 mm apart;
{iii} filling the regions between the wax lines with granules of tempered low iron glass, the glass granules being between approx. 2 mm and approx. 3 mm in size;
{iv} pouring liquid crystal resin to fill the region between the edging pieces to a depth exceeding that of the glass granules and allowing the liquid crystal resin to set to form an integrated layer of resin and glass granules;
{v} heating the work surface to melt at least some of the wax;
{vi} removing the integrated sheet of resin and glass granules from the work surface, orienting the layer at an angle to allow the melted wax to escape and further heating the wax if required.

The top layer can be cut to size if required before it is bonded to other parts of the solar panel.

Preferably the wax lines are applied through a nozzle which is between approx. 0.15 mm and approx. 0.2 mm in diameter. Preferably also the glass granules in step {iii} are filled to a depth of approx. 3 mm, i.e. to match the height of the wax lines, but in other embodiments the glass granules fill to a lesser or greater depth.

Desirably, the resin in step {iv} is filled to a level exceeding the height of the glass granules by approx. 2 mm.

It will be understood that the integrated sheet of resin and glass granules is inverted to form the top layer in the assembled solar panel, so that the glass granules which contact the work surface will form the top surface of the solar panel. The wax lines therefore create the grooves in the top layer.

A top layer constructed as described above is usually too smooth for a roadway and finishing steps are necessary. The finishing steps are preferably applied to the complete solar panel, i.e. after the top layer has been assembled to the layer of PV material and the base layer. The finishing steps preferably include the step of abrading or scuffing the top surface, desirably with thick grit (grade 20-40) on a belt or disc. The finishing steps preferably also include spraying a thin layer of crystal resin onto the (abraded) top surface and then pressing glass dust into the crystal resin, the particles of glass dust preferably being less than 1 mm in size. In order to ensure that the grooves are not inadvertently filled, a set of protective wires are preferably inserted into the grooves before the top surface is abraded or scuffed. A very thin layer of crystal resin can if desired be sprayed onto the top surface after the protective wires have been removed and any loose material has been removed from the grooves.

There is also provided a method of manufacturing the base layer of a solar panel for use in a roadway, the method comprising the steps of:
{i} mixing granular rubber with polyurethane resin;
{ii} putting the mixture into a mould and compressing the mixture under a load of approx. 100 tonnes until the resin sets;
{iii} adding further mixture to the mould on top of the set mixture of step {ii} and compressing the further mixture under a load of approx. 100 tonnes until the resin in the further mixture sets;
{iv} repeating step {iii} until the layer of rubber is approx. 115 mm thick;

Such a method can produce a base layer with a substantially planar top surface and a substantially planar bottom surface with no components embedded therein. If, however, it is desired to embed components in the base layer, for example a local controller and associated circuitry, and/or inductive charging coils, and/or a heat sink, and/or capacitors for energy storage, it is preferable to create recesses in the material of the base layer during moulding. The base of the mould, and/or the pressure plate, can include suitable projections to form the recesses. For example, recesses which are approx. 10 mm deep are desirable for locating inductive coils for vehicle charging and/or for the heat sink. The base layer is preferably constructed from separate sections with recesses formed in the top or bottom surface of a section whereby components can be located in the recesses and thereby embedded within the assembled base layer.

### BRIEF DESCRIPTION OF THE PREFERRED EMBODIMENTS

The invention will now be described in more detail, by way of example, with reference to the accompanying schematic drawings, in which:

FIG. 1 shows a solar roadway in use in a local and a national electricity network;

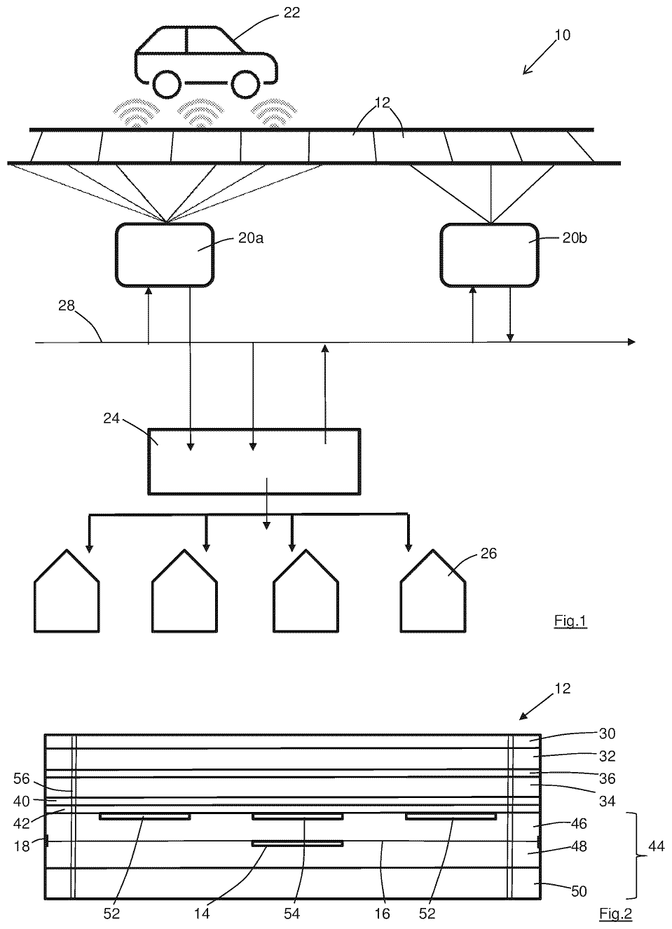

FIG. 2 shows a vertical cross-section through a solar panel according to an embodiment of the invention;

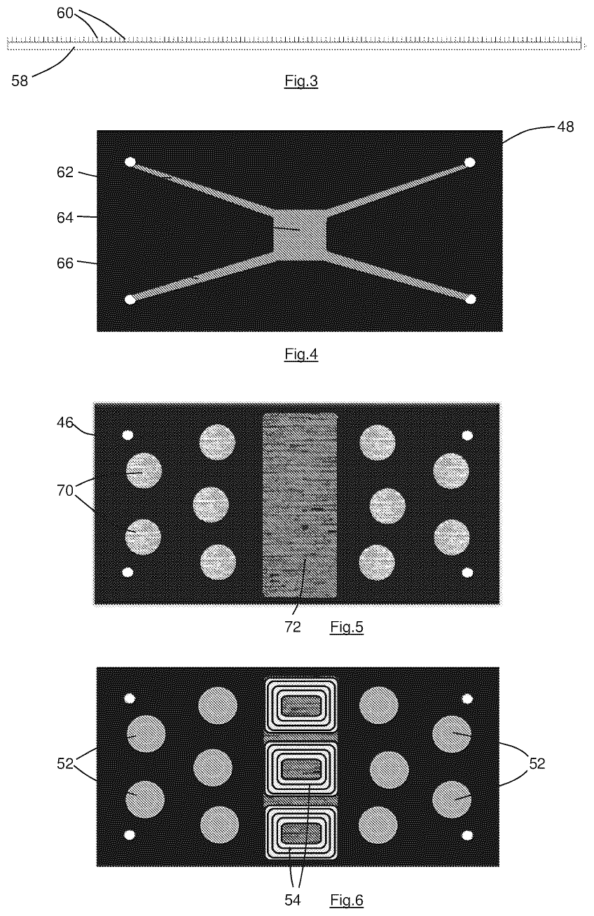

FIG. 3 shows a work surface during a step in the method to produce the top layer according to the invention;

FIG. 4 shows a plan view of a first part of the base layer during manufacture of the solar panel according to an embodiment of the invention;

FIG. 5 shows a plan view of a second part of a base layer during manufacture of the solar panel; and

FIG. 6 shows a view as FIG. 5 following fitment of inductive coils.

### DETAILED DESCRIPTION

FIG. 1 shows a schematic representation of a solar roadway 10 in use. The solar roadway 10 in this embodiment is constructed from a single line of solar panels 12 according to the invention, but it will be understood that a roadway could alternatively be constructed from two, three or more lines of solar panels 12. The solar panels 12 in each line can be offset from the solar panels 12 in the neighbouring line(s) to form a staggered array of solar panels if desired, but that is not necessary.

As shown in FIG. 2, each solar panel 12 has its own local controller 14 which is connected by wires 16 to electrical contacts 18 at edges of the solar panel 12. The electrical contacts 18 can engage the corresponding electrical contacts of neighbouring solar panels in the roadway, or can engage a common electrical line or bus (not shown) at the edge of the roadway, the common electrical line being connected to multiple solar panels 12. The panels 12 are physically separable so that an individual panel can be removed from the roadway for repair or replacement, if required.

As represented in FIG. 1, a group of solar panels 12 is connected to an external station 20a,b which is located alongside the roadway 10. Each external station 20a,b includes a group controller (not seen) to control and coordinate certain actions of all of the solar panels 12 in that group. The group controller can for example control the inductive charging of a passing vehicle 22 as described below.

Each external station 20a,b also includes means to receive electricity generated by the solar panels 12. The external stations 20a,b include means to deliver the electricity to users and may include means to temporarily store the electricity before delivery.

The external station 20a is connected to a local station 24 which provides a part of a local electricity network or micro-grid. In this embodiment the micro-grid comprises four properties 26 but other embodiments have more or fewer properties. Also, whilst the properties 26 are represented as domestic homes they could alternatively be commercial premises, factories or a mixture of premises requiring a supply of electricity.

In addition, whilst the micro-grid shown in FIG. 1 does not have any other local sources of electricity it could alternatively include other sources as well as other users of electricity.

The local station 24 is also connected to the national electricity network 28 and can deliver excess electricity to the national network when the local supply exceeds the local demand. The local station 24 can also receive electricity from the national network 28 when local demand exceeds local supply. The local station 24 can if desired also include means to store electricity.

The external station 20b is not connected to a micro-grid but is instead connected directly to the national network 28.

Both of the external stations 20a,b can receive electricity from the national network 28 when the demand for electricity by the solar panels 12 exceeds their supply, for example when it is desired to heat the roadway 10 and melt snow and ice during periods of darkness.

FIG. 1 also represents the inductive charging of the vehicle 22. As explained below, in preferred embodiments of the invention the solar panels 12 all include inductive charging coils 54 (FIG. 6) for charging the battery of the vehicle 22 as the vehicle moves along the roadway 10. The solar panels 12 can include load sensors to detect the position of the vehicle 22, the position of the vehicle being communicated to the external stations 20a,b as the vehicle passes those stations. In addition, the external stations 20a,b etc. are able to communicate with each other to provide advanced warning of the vehicle to neighbouring external stations. The charging coils 54 of each solar panel 12 can be activated as the vehicle passes, each solar panel 12 effectively firing a burst of energy to create a localised “carpet” of energy that travels under the vehicle 22 as it moves. The vehicle's battery can thereby be charged inductively as if the vehicle were stationary.

The structure of one embodiment of solar panel 12 according to the invention is shown in FIG. 2. This figure is not to scale and the vertical dimension of several of the layers is greatly exaggerated compared to the horizontal dimension, and to the vertical dimension of other layers, for clarity.

In general terms, the top layer 30 comprises tempered glass granules in crystal resin. Underneath the top layer is a first sheet of glass 32 and a second sheet of glass 34. Between the first and second sheets of glass is additional electrical componentry 36, namely LEDs which can be illuminated to provide information to the driver of vehicle 22, for example road markings and signage which are visible to the drivers of vehicles using the roadway 10. Between the top layer 30 and the first sheet of glass 32 are further additional heating elements and sensors (not shown in FIG. 1). The heating elements comprise looped electrical conductors made from graphene. The electrical conductors are effectively “etched” into the top surface of the first sheet of glass, specifically by atomic deposition by a laser of a thread of graphene oxide. In this preferred embodiment the sensors comprise temperature sensors and load sensors. It will be understood that sensors are optional and dependent upon the structure and functions of the solar panel—other embodiments can have no sensors, only temperature sensors, only load sensors, or additional sensors for additional functions as required.

As explained below, the top layer 30 is bonded to the first sheet of glass 32 by crystal resin. The first and second sheets of glass 32 and 34 are also bonded together by crystal resin with the LEDs 36 embedded in the crystal resin between the sheets 32 and 34.

Mounted to the bottom of the second sheet of glass 34 is the PV material, comprising a deposited layer 40 of cadmium telluride with a backing 42 of zinc magnesium oxide and copper thiocyanate.

In certain embodiments the base layer 44 is a single integral layer of rubber approx. 115 mm thick. In this embodiment, however, the solar panel 12 includes a base layer 44 made up of three separate sections, an upper section 46, a middle section 48 and a lower section 50.

The multi-part base layer 44 enables components to be located between adjacent sections of the base layer. In this embodiment the solar panel 12 includes a local controller 14 which is located between the upper section 46 and the middle section 48. This embodiment also includes inductive charging coils 52 and 54 which are located at the top of the upper section 46. The inductive charging coils 54 are relatively high capacity and are provided for vehicle charging. The inductive coils 52 are relatively low capacity and are provided to cooperate with heating coils to melt snow and ice.

The base layer can also include supercapacitors to store electrical energy, in which case the supercapacitors are preferably located between the middle section and the lower section.

The local controller 14 is connected to the PV material 40,42, to the inductive coils 52,54, and to all the other components of the solar panel 12. Suitable electrical connections run along one or other of the four vertical conduits 56 which are formed adjacent to the corners of the solar panel 12.

The vertical conduits 56 also accommodate fixing bolts which pass through the panel and secure the panel to the underlying ground. The cabling is located in a small conduit which lies next to the fixing bolt in use.

One method of constructing the top layer 30 is described below.
1. On a level stainless steel table 58 (FIG. 3) form a rectangle of edging pieces, the rectangle measuring 3.5 metres by 2.0 metres.
2. With a 3D wax printer having a 0.15-0.2 mm nozzle, deposit substantially parallel lines of wax to a height of 3 mm, the wax lines being substantially parallel to the short edges of the rectangle and with centres 5 mm apart.
3. Fill the regions between the wax lines with tempered glass granules with an approx. size of 2-3 mm.
4. Mix approx. 35 litres of crystal resin and pour the resin evenly over the glass granules and wax lines, covering the wax lines by approx. 2 mm.
5. Wait (approx. 24 hrs) for the crystal resin to set.
6. Heat the metal table gently from underneath to activate the wax back to liquid form and to release the sheet of glass granules and resin.
7. Hang the sheet of glass granules and resin under an infrared heater at an angle so that the excess wax can run off.
8. Cut the sheet to size if required (preferably 3.5 metres by 2.0 metres).

FIG. 3 shows a stage of this process, and in particular shows the parallel wax lines 60 formed onto the work surface 58.

One method of preparing the first sheet of glass 32 is described below.
1. An approx. 10 mm thick sheet of low iron glass is cut to a rectangular shape with a length of 3.5 metres and a width of 2.0 metres. Four holes are drilled through the sheet, one hole adjacent to each corner (the holes form part of the fixing bolt holes 56 and also the conduits of the assembled solar panel 12).
2. Temper and anneal the sheet of glass.
3. By way of atomic deposition, apply loops of graphene oxide thread to a chosen area of (what will become the top surface of) the sheet to form the heating elements, the graphene oxide thread covering approx. 1% of the chosen area.
4. Adhere thermal sensors to the same (top) surface and run the wires for the sensors to a respective drilled hole.

In this embodiment the heating elements operate inductively and so there is no wiring connected to the heating elements. In other embodiments, however, linear threads of graphene oxide can run to opposing edges of the sheet and be connected to wires located at the edges. For example, a copper ribbon can be laser-deposited to run perpendicular at both ends of each heating element to complete the circuit.

In addition, the present embodiment also has inductive coils 54 for vehicle charging and it is necessary that the inductive heating and inductive charging do not interfere. In this embodiment a strip approx. 350 mm wide across the centre of the glass sheet is reserved for vehicle charging and so the chosen area(s) for the heating elements are located only to either side of that central strip, as seen in FIG. 6.

One method of preparing the second sheet of glass 34 is described below.
1. An approx. 10 mm thick sheet of low iron glass is cut to a rectangular shape with a length of 3.5 metres and a width of 2.0 metres. Four holes are drilled through the sheet, similarly positioned to the holes in the first sheet of glass 32.
2. Temper and anneal the sheet of glass.
3. What will become the bottom surface of the sheet of glass is ultrasonically cleaned in Micro-90 detergent (available from St. Louis, Missouri, USA) and deionized water at 70° C.
4. The glass is fed through a PV plating line (such a plating line is available from Grenzebach, Germany or EcoProgetti, Italy) and a cadmium telluride (CdTe) plating material 40 is layered with the backing material 42 of Zinc Magnesium Oxide (ZMO) and copper thiocyanate (CuSCN) using ammonium hydroxide as the solvent for CuSCN deposition.
5. An 80 nm ZMO film is then deposited on the cleaned glass, using a radio frequency sputter system at ambient temperature. The deposition is conducted at 6 m Torr pressure under a mixed gas flow of 3% oxygen and 97% helium at a 25 W sputtering power, using a 2-inch ZMO target with 8 wt. % magnesium oxide.
6. An approx. 3.5 μm CdTe film is deposited in a close-space sublimation (CSS) chamber, with the source temperature of 560° C., the substrate temperature of 495° C., and a Materials 2020, 13, 1991 3 of 12 chamber pressure of 1 Torr. A CdCl2 activation treatment was carried out by drop-casting a saturated CdCl2 in methanol solution on the CdTe surface, followed with drying naturally and annealing at 420° C. for 20 min at 400 Torr with a 500 sccm helium gas flow.
7. After cooling down, the CdTe film is rinsed by methanol thoroughly to clean the excess CdCl2.
8. The contact points for the PV material are installed and the wiring harness is bound and insulated.

One method of bonding the first and second sheets of glass 32,34 is described below:
1. Provide a former with the dimensions 3.5 m by 2.0 m and with a surrounding wall.
2. Place the first sheet of glass 32 in the former, inverted.
3. Clean the exposed surface of the sheet of glass 32.
4. Pour in enough crystal resin to spread and cover the whole exposed surface of the first sheet of glass 32.
5. Prepare a TEC display LED of a chosen size (for example to span the distance between opposing long edges of the sheet) and push the LED matrix into the crystal resin. Pass the LED's data ribbon to the edge of the cast form and up the wall.
6. After approx. 1 hour pour in more crystal resin to give a total of approx. 5 mm coverage.
7. Lower the (inverted) second sheet of glass 36 into place on top of the first sheet 32 and clamp into place.
8. Ensure all air bubbles are removed and leave to set.
9. After approx. 48 Hrs remove the composite structure from the mould and rotate so that the first sheet 32 is uppermost.

One method for constructing the base layer 44 is described below:
1. Granulised tyre rubber waste material is mixed with polyurethane resin in the proportions 92%:8%. The mixture and the resulting base layer is chemically inert. There are no solvents within the blend, or added thereafter.
2. The mixture is placed into a first mould with a steel cast to form recesses for the inductive charging coils 52, 54 and compressed under a load of 100 tonnes until the polyurethane resin has hardened.
3. Further mixture is added to the mould and compressed under a load of 100 tonnes.
4. Further mixture is added so that the upper section 46 of the base layer is built up in thin layers until the desired thickness of the upper section is reached (approx. 40 mm).
5. Further mixture is placed into a second mould with a steel cast to form a recess for the local controller 14 and its electrical connectors. The mixture is compressed under a load of 100 tonnes until the polyurethane resin has hardened.
6. Further mixture is added so that the middle section 48 of the base layer is built up in thin layers until the desired thickness of the middle section is reached (approx. 40 mm).
7. Further mixture is placed into a third mould with a steel cast to form recesses for the (optional) supercapacitors. The mixture is compressed under a load of 100 tonnes until the polyurethane resin has hardened.
8. Further mixture is added so that the lower section 50 of the base layer is built up in thin layers until the desired thickness of the lower section is reached (approx. 35 mm).

A top view of the middle section 48 of the base layer 44 is shown in FIG. 4. A plastic former 62 is pressed into the recess formed in the top surface of the middle section. The former is preferably made from waste or non-recyclable plastics and has a central receptacle 64 and four branches 66. The receptacle 64 is sized to accommodate the local controller 14 and the branches 66 are sized to pass electrical cabling between the local controller and the other electrical componentry of the solar panel 12. Each of the branches 66 runs to a hole adjacent to a respective corner of the section, and which holes will form parts of the conduits 56. The holes are drilled through the middle section 48, and are aligned with the holes drilled through the first and second glass sheets 32, 34. Similar holes are drilled through the upper section 46.

A heat sink can if desired be installed adjacent to the local controller 14 in order to dissipate the heat generated by the local controller in use.

In addition, if it is desired for the solar panel to have means to store electricity, one or more capacitors (or supercapacitors) are preferably installed into the base layer. The temporary storage of electricity in supercapacitors is expected to be beneficial in embodiments providing vehicle charging as electrical energy generated by the PV material can be stored in the supercapacitor and discharged rapidly through the charging coils 54.

A top view of the upper section 46 of the base layer 44 is shown in FIG. 5, and a similar view is seen in FIG. 6 with the inductive coils 52, 54 located in their respective recesses. The recesses 70 accommodate the inductive coils 52 for the heating elements. The recesses 72 accommodate the vehicle charging coils 54. As above stated, the vehicle charging coils 54 occupy a central strip across the base layer 44, and therefore across the solar panel 12, and the inductive coils 52 and heating elements are located outside that central strip.

The location and orientation of the vehicle charging coils can be varied as desired, to suit the direction of travel of the vehicle 22. In this embodiment the charging coils 54 are laid in a line parallel to the shorter edges of the solar panel 12 as it is intended to form a roadway 10 with the short edges parallel to the direction of travel. In other arrangements the longer edges might be parallel to the direction of travel, in which case the charging coils 54 would preferably be oriented parallel with the longer edges.

After the local controller 14 and its cabling have been installed in the plastic former 62, the former is filled with resin to match the level of the surrounding section. A resin material is also used to infill any gaps remaining in the recesses 70, 72 so that each of the sections of the base layer has a flat top and bottom surface. The sections are bonded together with a rubber resin and the resin is also applied to seal the joints between the sections.

One method of mounting the glass layers to the base layer is described below.
1. Provide a former with dimensions with a length approx. 5 mm larger than the length of the sheets of glass 32, 34 and base layer 44 and a width approx. 5 mm larger than the length of the sheets of glass and base layer and with a 100 mm surrounding wall.
2. Locate the base layer 44 in the former with an approx. 2.5 mm gap between the edges of the base layer and the surrounding wall.
3. Hold the wiring for the electrical contacts 18 away from the base layer 44.
4. Apply a silicon dam to the outer edges of the base layer.
5. Apply a non-conductive adhesive between the top of the base layer 44 and the backing layer 42 and secure the sheets of glass 32,34 and PV layers 40,42 to the base layer 44.
6. Fill the gap around the base layer 44 with a rubber resin to the level of the top of the base layer.
7. When the rubber resin has set, fill the gap around the glass layers with crystal resin to the level of the top of the first sheet of glass 32.
8. When the crystal resin around the glass layers has set, remove the silicon dam.
9. Pour a thin layer of crystal resin onto the top sheet of glass 32.
10. When the thin layer of crystal resin is tacky insert the top layer 30 and press into place.
11. Insert protective wires into the grooves of the top layer 30.
12. Abrade or scuff the top surface of the top layer 30 with a coarse grit sander.
13. Apply a thin coat of crystal resin by spray or roller onto the abraded top surface.
14. When the thin coat of crystal resin is tacky press particles of glass dust into the resin, the particles of glass dust preferably being less than 1 mm in size.
15. After approx. 12 hours remove the protective wires and remove any loose material from the grooves.
16. Apply a very thin layer of crystal resin to form the integrated solar panel 12.

### LIST OF REFERENCE NUMERALS

10 solar roadway
12 solar panel
14 local controller
16 wires
18 electrical contacts
20 external station
22 vehicle
24 local station
26 properties
28 national electricity network
30 top layer
32 first sheet of glass
34 second sheet of glass
36 LEDs
40 PV material
42 backing for the PV material
44 base layer
46 upper section of base layer
48 middle section of base layer
50 lower section of base layer
52 inductive charging coils
54 inductive charging coils
56 conduits
58 table
60 lines of wax
62 plastic former
64 central receptacle
66 branches
70 recesses
72 recesses

1. A solar panel for a roadway, the panel comprising a base layer, a layer including a PV material, and a top layer, the top layer comprising tempered glass granules with an average size of approximately 2-3 mm embedded in a crystal resin, the top layer having multiple substantially parallel grooves formed therein, the grooves being approximately 3 mm deep.

2. A solar panel according to claim 1 in which the centres of the grooves are approximately 5 mm apart.

3. A solar panel according to claim 1 in which the resin has a similar transparency and optical clarity to that of the tempered glass granules.

4. A solar panel according to claim 1 in which the crystal resin is of a type which sets in ultraviolet light.

5. A solar panel according to claim 1 in which there is a first sheet of glass between the top layer and the PV layer.

6. (canceled)

7. A solar panel according to claim 5 in which the first sheet of glass is bonded to the top layer by crystal resin.

8. A solar panel according to claim 5 in which one or more heating elements is located between the top layer and the first sheet of glass, the heating element(s) covering approximately 1% of the total plan area of the solar panel.

9.-10. (canceled)

11. A solar panel according to claim 5 in which there is a second sheet of glass between the first sheet of glass and the PV layer.

12. A solar panel according to claim 11 in which the first and second sheets of glass comprise tempered low iron glass.

13. (canceled)

14. A solar panel according to claim 11 in which LEDs and associated circuitry are located between the first and second sheets of glass.

15.-17. (canceled)

18. A solar panel according to claim 1 in which the PV material comprises cadmium telluride and a backing layer of zinc magnesium oxide and copper thiocyanate.

19. A solar panel according to claim 1 having a local controller located in the base layer.

20. A solar panel according to claim 1 in which the base layer includes a rubber material comprising granular and fibrous rubber and a polyurethane binder, in which the mixture of rubber granules and binder comprises approximately 92% rubber and approximately 8% polyurethane resin.

21.-23. (canceled)

24. A solar panel according to claim 1 in which the base layer includes at least one section defined by a plastics insert, and in which an electrical component is located in the section and embedded in resin.

25.-26. (canceled)

27. A solar roadway constructed from a plurality of solar panels according to claim 1.

28. A method of manufacturing the top layer of a solar panel according to claim 1, the method comprising the steps of:
{i} locating edging pieces upon a flat work surface to define a region between the edging pieces, the region being in the shape of a rectangle with chosen dimensions;
{ii} applying continuous and substantially parallel lines of wax to the work surface between the edging pieces, the lines of wax being approximately 3 mm high;
{iii} filling the regions between the wax lines with granules of tempered low iron glass, the glass granules being between approximately 2 mm and approximately 3 mm in size;
{iv} pouring liquid crystal resin to fill the region between the edging pieces to a depth exceeding that of the glass granules and allowing the liquid crystal resin to set to form an integrated layer of resin and glass granules;
{v} heating the work surface to melt at least some of the wax;
{vi} removing the integrated sheet of resin and glass granules from the work surface, orienting the layer at an angle to allow the melted wax to escape and further heating the wax if required.

29. A method according to claim 28 in which the parallel lines of wax in step {i} are centred approximately 5 mm apart, in which the glass granules in step {iii} are filled to a depth of approximately 3 mm, and in which the resin in step {iv} is filled to a level exceeding the height of the glass granules by approximately 2 mm.

30.-31. (canceled)

32. A method according to claim 28 including the further steps of abrading the top layer, spraying a thin layer of crystal resin onto the abraded top layer and then pressing glass dust into the crystal resin.

33. A method according to claim 32 in which the particles of glass dust are less than 1 mm in size.

34. A method of manufacturing the base layer of a solar panel according to claim 1, the method comprising the steps of:
{i} mixing granular rubber with polyurethane resin;
{ii} putting the mixture of step {i} into a mould and compressing the mixture under a load of approximately 100 tonnes until the resin sets;
{iii} adding further mixture of step {i} to the mould on top of the set mixture of step {ii} and compressing the further mixture under a load of approximately 100 tonnes until the resin in the further mixture sets;
{iv} repeating step {iii} until the layer of rubber reaches the desired thickness.

35. A method according to claim 34 in which the base layer is constructed in two or more sections, and in which a plastics insert is added to at least one of the sections.

36. (canceled)
